(19) United States
(12) Patent Application Publication
(10) Pub. No.: US 2026/0096389 A1
(43) Pub. Date: Apr. 2, 2026

(54) CONVEYANCE DEVICE AND CONVEYANCE METHOD

(71) Applicant: PANASONIC INTELLECTUAL PROPERTY MANAGEMENT CO., LTD., Osaka (JP)

(72) Inventors: Takashi SASASHIGE, Osaka (JP); Shoji KIRITA, Shiga (JP)

(21) Appl. No.: 19/324,730

(22) Filed: Sep. 10, 2025

(30) Foreign Application Priority Data
Oct. 1, 2024 (JP) 2024-172770

(51) Int. Cl. H01L 21/67; H01L 21/304; H01L 21/677; H01L 21/78

(52) U.S. Cl. CPC H10P 72/0604; H10P 52/00; H10P 54/00; H10P 72/3218

(57) ABSTRACT

A conveyance device includes: a container that contains a processing target; a conveyor that conveys the processing target along a predetermined conveyance path between the container and a processor that processes the processing target; an ionizer that ejects neutralization air toward the processing target conveyed by the conveyor; and a controller that controls the conveyor.

### BACKGROUND

### 1. Technical Field

The present disclosure relates to a conveyance device and a conveyance method.

### 2. Description of the Related Art

Conventionally, a technique for neutralizing a semiconductor substrate is known (for example, Patent Literature 1. Patent Literature 1 discloses “A method for fabricating a semiconductor integrated circuit device, including the steps of: (a) connecting an internal space of a first sealed semiconductor storage container in a sealed state in which a plurality of wafers is accommodated in a grounded state to a local clean chamber of a first wafer processing apparatus in a state in which cleanliness is maintained; (b) in the connected state, transferring all or some of the plurality of wafers accommodated in the first semiconductor storage container by a conveyance mechanism provided in the local clean chamber, thereby accommodating the wafers in a wafer processor of the first wafer processing apparatus; (c) performing first processing on the wafers accommodated in the first wafer processor; (d) after the step (c), transferring the processed wafers by the conveyance mechanism to accommodate the wafers in the first semiconductor storage container in a grounded state; (e) neutralizing the processed wafers after the step (c) and before or during the step (d); and (f) after the step (d), releasing the connected state between the first semiconductor storage container and the local clean chamber to return the first semiconductor storage container to a sealed state”.

### CITATION LIST

### Patent Literature

PTL 1: Unexamined Japanese Patent Publication No. 2002-118161

### SUMMARY

However, Patent Literature 1 discloses the technique for neutralizing the wafer (or a processing target), but does not describe that a condition for neutralization is optimized according to a state of the processing target (for example, a charge amount of the processing target). In such a situation, an object of the present disclosure is to perform neutralization according to a state of a processing target.

One aspect of the present disclosure relates to a conveyance device. The conveyance device including: a container that contains a processing target; a conveyor that conveys the processing target along a predetermined conveyance path between the container and a processor that processes the processing target; an ionizer that ejects neutralization air toward the processing target conveyed by the conveyor; and a controller that controls the conveyor, in which the processing target is held by a frame-attached holding sheet, the controller causes the conveyor to execute a first conveyance operation of delivering the processing target taken out from the container to the processor, and a second conveyance operation of delivering the processing target received from the processor to the container, and a neutralization condition of the ionizer in the first conveyance operation and a neutralization condition of the ionizer in the second conveyance operation are individually set.

Another aspect according to the present disclosure relates to a conveyance method. The conveyance method executed in a conveyance device including a container that contains a processing target, a conveyor that conveys the processing target along a predetermined conveyance path between the container and a processor that processes the processing target, and an ionizer that ejects neutralization air toward the processing target conveyed by the conveyor, in which the processing target is held by a frame-attached holding sheet, the conveyance method including: a first conveyance step of taking out the processing target from the container and then delivering the taken-out processing target to the processor by the conveyor; and a second conveyance step of receiving the processing target from the processor and then delivering the received processing target to the container by the conveyor, in which a neutralization condition of the ionizer in the first conveyance step and a neutralization condition of the ionizer in the second conveyance step are individually set.

According to the present disclosure, neutralization according to a state of the processing target can be performed.

### BRIEF DESCRIPTION OF THE DRAWINGS

FIG. 1 is a front view schematically illustrating a configuration of a conveyance device according to a first exemplary embodiment;

FIG. 2 is a plan view schematically illustrating the configuration of the conveyance device according to the first exemplary embodiment;

FIGS. 3A and 3B are plan views for explaining a predetermined conveyance path, in which FIG. 3A illustrates an example of a conveyance path in a first conveyance operation, and FIG. 3B illustrates an example of a conveyance path in a second conveyance operation;

FIGS. 4A and 4B are cross-sectional views illustrating an example of a substrate, in which FIG. 4A illustrates a wafer held on a frame-attached holding sheet, and FIG. 4B illustrates a plurality of element chips held on the frame-attached holding sheet;

FIG. 5 is a front view schematically illustrating a main part of a conveyance device according to a second exemplary embodiment; and

FIG. 6 is a front view schematically illustrating a main part of a conveyance device according to a third exemplary embodiment.

### DETAILED DESCRIPTIONS

Exemplary embodiments of a conveyance device and a conveyance method according to the present disclosure will be described below by way of examples. However, the present disclosure is not limited to the examples described below. Although specific numerical values and materials may be provided as examples in the description below, other numerical values and materials may be used as long as an effect of the present disclosure can be obtained.

### Conveyance Device

A conveyance device according to the present disclosure is a device that conveys a processing target (for example, a substrate) between a container and a processor. The processor may be a plasma processor that performs plasma processing on the processing target. Examples of the plasma processing include plasma dicing, plasma cleaning, plasma etching, plasma ashing, plasma CVD, and the like. The conveyance device according to the present disclosure includes the container, a conveyor, an ionizer, and a controller.

The container contains the processing target. The processing target is held by a frame-attached holding sheet. The container may be, for example, a load port including a front opening unified pod (FOUP). The container may contain the plurality of processing targets.

The conveyor conveys the processing target along a predetermined conveyance path between the container and the processor that processes the processing target. The conveyor may hold the processing target via the frame-attached holding sheet and convey the processing target. The conveyor may include a robot arm movable between the container and the processor.

The ionizer ejects neutralization air toward the processing target conveyed by the conveyor. The ionizer is a device that ionizes surrounding air by corona discharge to generate positive and negative ions. The neutralization air is air containing ions generated in this manner, and can neutralize a charged processing target by blowing the neutralization air. The ionizer may be disposed on at least one of an upper side and a lower side of the conveyor.

The controller controls the conveyor. The controller may include an arithmetic device and a storage device in which a program executable by the arithmetic device (for example, a program for causing a computer to execute the conveyance method according to the present disclosure) is stored. The controller causes the conveyor to perform a first conveyance operation and a second conveyance operation. The first conveyance operation is an operation of delivering the processing target taken out from the container (that is, the processing target before processing) to the processor. The second conveyance operation is an operation of delivering the processing target received from the processor (that is, the processing target after being processed) to the container.

In both the first conveyance operation and the second conveyance operation, the processing target to be conveyed can be neutralized by the ionizer, and a neutralization condition of the ionizer in the first conveyance operation and a neutralization condition of the ionizer in the second conveyance operation are individually set. As a result, even when a state of the processing target (for example, a charge amount of the processing target) in the first conveyance operation and a state of the processing target in the second conveyance operation are different from each other, it is possible to neutralize the processing target under the suitable neutralization conditions. Note that the neutralization condition of the ionizer in the first conveyance operation and the neutralization condition of the ionizer in the second conveyance operation may be the same or different from each other.

The conveyance device may further include: a first measurement unit that is disposed on a side of the container in the conveyance path and measures a charge amount of the processing target taken out from the container by the conveyor; and a second measurement unit that is disposed on a side of the processor in the conveyance path and measures a charge amount of the processing target received by the conveyor from the processor. The controller may determine the neutralization condition in the first conveyance operation based on the charge amount measured by the first measurement unit when the conveyor performs the first conveyance operation, and determine the neutralization condition in the second conveyance operation based on the charge amount measured by the second measurement unit when the conveyor performs the second conveyance operation. In this configuration, the first measurement unit measures the charge amount of the processing target immediately after the start of the first conveyance operation, and the second measurement unit measures the charge amount of the processing target immediately after the start of the second conveyance operation. Then, the neutralization condition in the first conveyance operation is determined based on a measurement result of the first measurement unit, and the neutralization condition in the second conveyance operation is determined based on a measurement result of the second measurement unit. Therefore, the neutralization condition in each conveyance operation can be appropriately set according to the charge amount of the processing target. Each of the first measurement unit and the second measurement unit may be, for example, an electrostatic potential sensor that detects potential of static electricity charged in the processing target. The first measurement unit may be disposed on an upstream side of a neutralization position set in a region where a distance from the ionizer is less than or equal to 250 mm in the conveyance path of the first conveyance operation. The second measurement unit may be disposed on an upstream side of a neutralization position set in a region where a distance from the ionizer is less than or equal to 250 mm in the conveyance path of the second conveyance operation.

The neutralization condition may include an air volume of the neutralization air ejected from the ionizer. As the air volume of the neutralization air is larger, the processing target can be strongly neutralized. Therefore, the air volume of the neutralization air may be set to be larger as the charge amount of the processing target is larger. This makes it possible to neutralize the processing target under the neutralization condition more suitable for the state of the processing target.

The neutralization condition may include a stay time at the neutralization position set in the region where the distance from the ionizer is less than or equal to 250 mm, of the processing target conveyed by the conveyor. The neutralization position may be set on a leeward side of the ionizer, or may be particularly set below the ionizer. The neutralization position may be set in a region where the distance from the ionizer is less than or equal to 200 mm, less than or equal to 180 mm, less than or equal to 160 mm, less than or equal to 140 mm, or less than or equal to 120 mm. The longer the stay time of the processing target at such a neutralization position is, the stronger the neutralization of the processing target can be performed. Therefore, the stay time may be set to be longer as the charge amount of the processing target is larger. This makes it possible to neutralize the processing target under the neutralization condition more suitable for the state of the processing target.

The controller may adjust the stay time by adjusting a stop time of the processing target at the neutralization position. As the stop time of the processing target at the neutralization position is longer, the stay time is longer, and the processing target can be strongly neutralized. Therefore, the stop time may be set to be longer as the charge amount of the processing target is larger. The stop time of the processing target at the neutralization position may be, for example, from 0.5 seconds to 3 seconds inclusive, from 0.5 seconds to 2 seconds inclusive, or from 0.5 seconds to 1 second inclusive.

The controller may adjust the stay time by adjusting a conveyance speed of the processing target at the neutralization position. As the conveyance speed of the processing target at the neutralization position decreases, the stay time increases, and the processing target can be strongly neutralized. Therefore, the conveyance speed may be set so as to decrease as the charge amount of the processing target increases. The conveyance speed of the processing target at the neutralization position may be, for example, from 40 mm/s to 500 mm/s inclusive.

The neutralization condition may include a distance between the processing target and the ionizer at the neutralization position set in the region where the distance from the ionizer is less than or equal to 250 mm. As the distance between the processing target and the ionizer at the neutralization position is smaller, the processing target can be strongly neutralized. Therefore, the distance may be set so as to decrease as the charge amount of the processing target increases. This makes it possible to neutralize the processing target under the neutralization condition more suitable for the state of the processing target. The distance between the processing target and the ionizer at the neutralization position may be, for example, from 50 mm to 250 mm inclusive.

The ionizer may include a first ionizer that ejects neutralization air to the processing target in the first conveyance operation from above, and a second ionizer that ejects neutralization air to the processing target in the second conveyance operation from below. The first ionizer may be disposed above the conveyor. The first ionizer may be a fixed ionizer. The second ionizer may be a movable ionizer provided in the conveyor, or may be a fixed ionizer disposed below the conveyor. This configuration is particularly suitable when the processing target (for example, a substrate) is singulated in the processor. That is, when the neutralization air is ejected from above to the processing target after the processing target is singulated, there is a possibility that a defect such as flying up of fine particles attached to the processing target occurs. On the other hand, in the present configuration, the second ionizer ejects the neutralization air to the singulated processing target from below, that is, from a side of the frame-attached holding sheet that holds the processing target, so that such a defect hardly occurs.

In the first conveyance operation, the processing target that the conveyor takes out from the container and delivers to the processor may be a wafer before singulation held on the frame-attached holding sheet. The processor may be a plasma processing chamber that singulates a wafer into a plurality of element chips. In the second conveyance operation, the processing target that the conveyor receives from the processor and delivers to the container may be a plurality of element chips held on the frame-attached holding sheet. In this configuration, the wafer delivered to the processor by the first conveyance operation is singulated into a plurality of element chips by plasma dicing in the plasma processing chamber, and the plurality of element chips is delivered to the container in the second conveyance operation while being held on the frame-attached holding sheet. In the conveyance device according to the present disclosure, a neutralization condition for the wafer before singulation and a neutralization condition for the plurality of element chips can be appropriately set individually.

### Conveyance Method

A conveyance method according to the present disclosure may be executed in the conveyance device according to the present disclosure, or may be executed in the other conveyance device. The conveyance method according to the present disclosure is a conveyance method executed in a conveyance device including a container that contains a processing target held by a frame-attached holding sheet, a conveyor that conveys the processing target along a predetermined conveyance path between the container and a processor that processes the processing target, and an ionizer that ejects neutralization air toward the processing target conveyed by the conveyor. The conveyance method according to the present disclosure includes a first conveyance step and a second conveyance step.

In the first conveyance step, the conveyor takes out the processing target from the container, and then delivers the taken-out processing target to the processor. In other words, in the first conveyance step, the conveyor conveys the processing target before processing from the container to the processor.

In the second conveyance step, the conveyor receives the processing target from the processor and then delivers the received processing target to the container. In other words, in the second conveyance step, the conveyor conveys the processing target after being processed from the processor to the container.

In both the first conveyance step and the second conveyance step, the processing target to be conveyed can be neutralized by the ionizer, and a neutralization condition of the ionizer in the first conveyance step and a neutralization condition of the ionizer in the second conveyance step are individually set. As a result, even when a state of the processing target (for example, a charge amount of the processing target) in the first conveyance step and a state of the processing target in the second conveyance step are different from each other, it is possible to neutralize the processing target under the suitable neutralization conditions.

The conveyance method may further include: a first measurement step of measuring a charge amount of the processing target taken out from the container by the conveyor on the side of the container in the conveyance path; a second measurement step of measuring a charge amount of the processing target received by the conveyor from the processor on the side of the processor in the conveyance path; a first determination step of determining a neutralization condition in the first conveyance step based on the charge amount measured in the first measurement step; and a second determination step of determining a neutralization condition in the second conveyance step based on the charge amount measured in the second measurement step. In this case, the neutralization condition in each conveyance step can be appropriately set according to the charge amount of the processing target. Each of the first measurement step and the second measurement step may be executed using, for example, an electrostatic potential sensor that detects potential of static electricity charged in the processing target.

The neutralization condition may include an air volume of the neutralization air ejected from the ionizer.

The neutralization condition may include a stay time at a neutralization position set in a region where a distance from the ionizer is less than or equal to 250 mm, of the processing target conveyed by the conveyor.

The conveyance method may further include a first adjustment step of adjusting the stay time by adjusting a stop time of the processing target at the neutralization position.

The conveyance method may further include a second adjustment step of adjusting the stay time by adjusting a conveyance speed of the processing target at the neutralization position.

The neutralization condition may include a distance between the processing target and the ionizer at the neutralization position set in the region where the distance from the ionizer is less than or equal to 250 mm.

The ionizer may include a first ionizer that ejects neutralization air from above to the processing target in the first conveyance step, and a second ionizer that ejects neutralization air from below to the processing target in the second conveyance step.

In the first conveyance step, the processing target that the conveyor takes out from the container and delivers to the processor may be a wafer before singulation held on the frame-attached holding sheet. The processor may be a plasma processing chamber that singulates a wafer into a plurality of element chips. In the second conveyance step, the processing target that the conveyor receives from the processor and delivers to the container may be a plurality of element chips held on the frame-attached holding sheet.

As described above, according to the present disclosure, it is possible to perform neutralization according to the state of the processing target by individually setting the neutralization condition of the ionizer in each conveyance operation.

Hereinafter, one example of the conveyance device and the conveyance method according to the present disclosure will be specifically described with reference to the drawings. The above-described configuration elements and steps can be applied to configuration elements and steps of the conveyance device and the conveyance method of the one example described below. The configuration elements and steps of the conveyance device and the conveyance method of the one example described below can be changed based on the above description. Matters described below may be applied to the exemplary embodiment described above. Among the configuration elements and steps of the conveyance device and the conveyance method of the one example described below, configuration elements and steps that are not essential for the conveyance device and the conveyance method according to the present disclosure may be omitted. Note that the drawings described below are schematic, and thus do not accurately reflect the shape and number of actual members.

### First Exemplary Embodiment

A first exemplary embodiment of the present disclosure will be described. Hereinafter, conveyance device 10 of the present exemplary embodiment will be first described, and then, a conveyance method of the present exemplary embodiment will be described.

### Conveyance Device

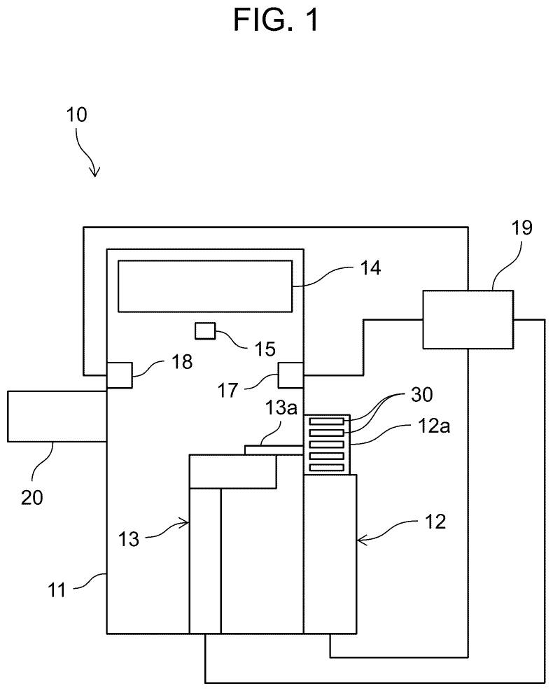

As illustrated in FIGS. 1 to 4, conveyance device 10 of the present exemplary embodiment includes housing 11, container 12, conveyor 13, fan filter unit 14, ionizer 15, aligner 16, first measurement unit 17, second measurement unit 18, and controller 19.

Housing 11 is a hollow box body formed in a substantially rectangular parallelepiped shape. Housing 11 accommodates conveyor 13, fan filter unit 14, ionizer 15, aligner 16, first measurement unit 17, and second measurement unit 18. At least one (in this example, two) processor 20 that processes substrate 30 is connected to housing 11 through an openable and closable opening (not illustrated). Processor 20 of the present exemplary embodiment includes a plasma processing chamber that singulates a wafer before singulation held on a frame-attached holding sheet into a plurality of element chips. Substrate 30 is one example of a processing target.

Container 12 contains substrate 30 held by the frame-attached holding sheet. Container 12 of the present exemplary embodiment is configured by a load port including FOUP 12a that contains substrate 30. An internal space of FOUP 12a (that is, a space in which substrate 30 is contained) can communicate with an internal space of housing 11 through an opening (not illustrated) formed in housing 11 as necessary. The number of containers 12 is not particularly limited, and in this example, two containers 12 are provided.

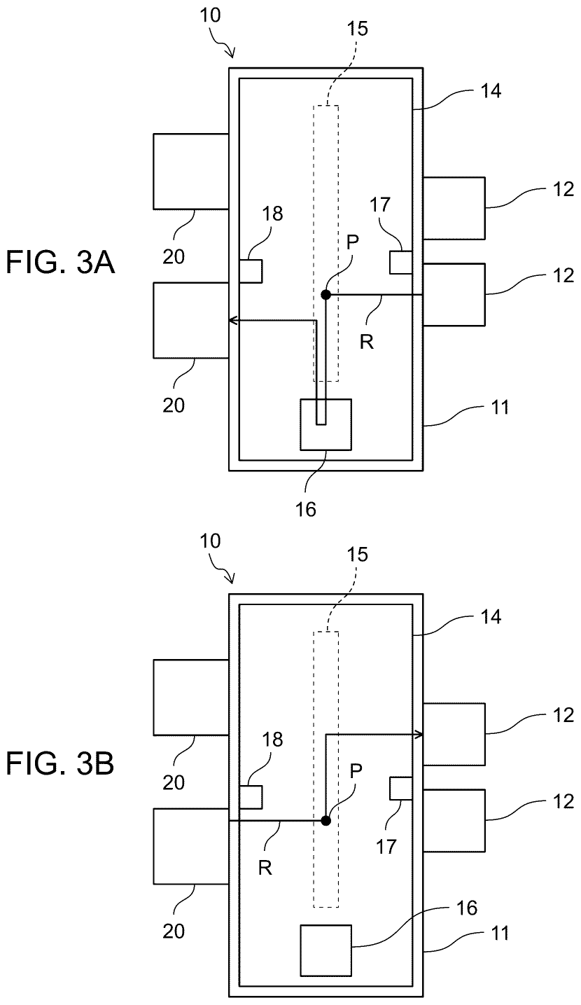

Conveyor 13 is disposed in a lower region of the internal space of housing 11. Conveyor 13 conveys substrate 30 between container 12 and processor 20 along predetermined conveyance path R (see FIGS. 3A and 3B). Conveyor 13 of the present exemplary embodiment includes a conveyance robot having conveyance arm 13a.

Fan filter unit 14 is disposed in an upper region of the internal space of housing 11. Fan filter unit 14 includes at least one (in this example, two) fan (not illustrated), and generates a downward air flow by the fan. By this air flow, neutralization air (that is, air containing ions) generated by ionizer 15 is carried to substrate 30.

Ionizer 15 is provided below fan filter unit 14 in the internal space of housing 11. Ionizer 15 ejects neutralization air toward substrate 30 (in this example, downward) conveyed by conveyor 13. Charged substrate 30 can be neutralized by the neutralization air.

Aligner 16 is disposed at an end of the internal space of housing 11 when viewed from above. Aligner 16 is configured to adjust a position of substrate 30 being conveyed from container 12 to processor 20 by conveyor 13 (that is, in a first conveyance operation to be described later).

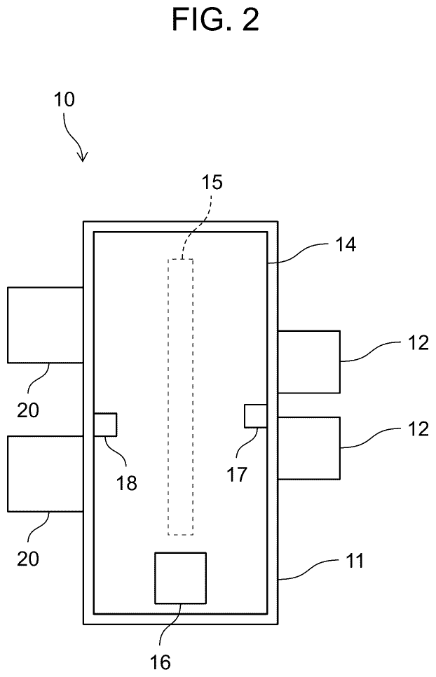

First measurement unit 17 is disposed on a side of container 12 (right side in FIGS. 1 and 2) in conveyance path R in the internal space of housing 11. First measurement unit 17 measures a charge amount of substrate 30 taken out from container 12 by conveyor 13. Information on a measurement result of first measurement unit 17 is sent to controller 19.

Second measurement unit 18 is disposed on a side of processor 20 (left side in FIGS. 1 and 2) in conveyance path R in the internal space of housing 11. Second measurement unit 18 measures a charge amount of substrate 30 received by conveyor 13 from processor 20. Information on a measurement result of second measurement unit 18 is sent to controller 19.

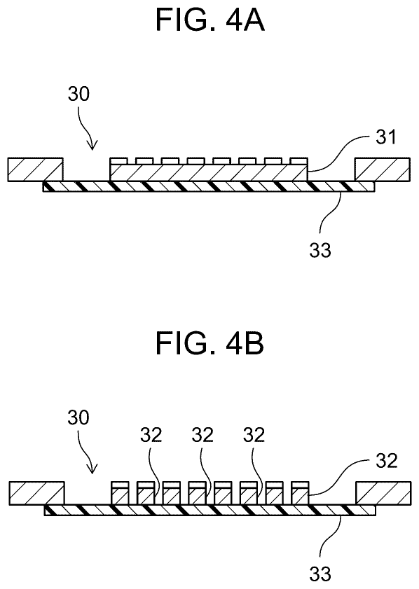

Controller 19 controls conveyor 13. More specifically, controller 19 causes conveyor 13 to perform the first conveyance operation of delivering substrate 30 taken out from container 12 to processor 20 via aligner 16 (FIG. 3A) and a second conveyance operation of delivering substrate 30 received from processor 20 to container 12 (FIG. 3B). In the first conveyance operation, substrate 30 taken out from container 12 by conveyor 13 and delivered to processor 20 is wafer 31 before singulation held on frame-attached holding sheet 33 (FIG. 4A). Wafer 31 is singulated into a plurality of element chips 32 in processor 20 (FIG. 4B). In the second conveyance operation, substrate 30 received by conveyor 13 from processor 20 and delivered to container 12 is the plurality of element chips 32 held on frame-attached holding sheet 33. Note that controller 19 may also control container 12 and conveyor 13.

Here, a neutralization condition of ionizer 15 in the first conveyance operation and a neutralization condition of ionizer 15 in the second conveyance operation are individually set. The neutralization condition in the first conveyance operation is determined by controller 19 based on the charge amount of substrate 30 measured by first measurement unit 17. The neutralization condition in the second conveyance operation is determined by controller 19 based on the charge amount of substrate 30 measured by second measurement unit 18.

As the neutralization condition in each conveyance operation, an air volume of neutralization air ejected from ionizer 15, a stay time at neutralization position P (that is, a predetermined position set in a region where a distance from ionizer 15 is less than or equal to 250 mm and indicated by a black dot in FIG. 3) of substrate 30 conveyed by conveyor 13, and a distance between substrate 30 and ionizer 15 at neutralization position P can be exemplified. Note that the stay time of substrate 30 at neutralization position P may be adjusted by controller 19 adjusting a stop time of substrate 30 at neutralization position P and/or by controller 19 adjusting a conveyance speed of substrate 30 at neutralization position P.

Neutralization position P in the first conveyance operation may be a position closest to ionizer 15 in conveyance path R in the first conveyance operation (in this example, the highest position). Neutralization position P in the second conveyance operation may be a position closest to ionizer 15 in conveyance path R in the second conveyance operation (in this example, the lowest position).

### Conveyance Method

Next, a conveyance method of the present exemplary embodiment will be described. The conveyance method of the present exemplary embodiment may be executed by conveyance device 10 of the present exemplary embodiment. The conveyance method of the present exemplary embodiment includes a first conveyance step, a second conveyance step, a first measurement step, a second measurement step, a first determination step, and a second determination step.

In the first conveyance step, conveyor 13 takes out substrate 30 (specifically, wafer 31 before singulation held on frame-attached holding sheet 33) from container 12, and then delivers taken-out substrate 30 to processor 20 via aligner 16.

In the second conveyance step, conveyor 13 receives substrate 30 (specifically, a plurality of element chips 32 held on frame-attached holding sheet 33) from processor 20, and then delivers received substrate 30 to container 12.

Here, a neutralization condition of ionizer 15 in the first conveyance step and a neutralization condition of ionizer 15 in the second conveyance step are individually set.

As an example of the neutralization condition in each conveyance step, the same neutralization condition as described above can be exemplified.

In the first measurement step, a charge amount of substrate 30 taken out from container 12 by conveyor 13 is measured on the side of container 12 in conveyance path R in the first conveyance step.

In the second measurement step, a charge amount of substrate 30 received by conveyor 13 from processor 20 is measured on the side of processor 20 in conveyance path R in the second conveyance step.

In the first determination step, a neutralization condition in the first conveyance step is determined based on the charge amount of substrate 30 measured in the first measurement step.

In the second determination step, a neutralization condition in the second conveyance step is determined based on the charge amount of substrate 30 measured in the second measurement step.

### Second Exemplary Embodiment

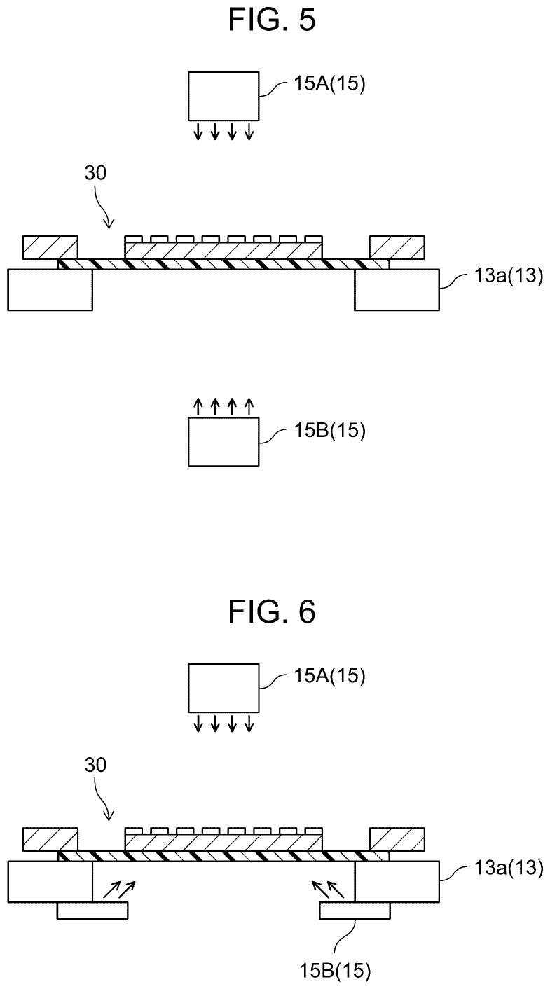

A second exemplary embodiment of the present disclosure will be described. Conveyance device 10 of the present exemplary embodiment is different from that of the first exemplary embodiment in that ionizer 15 includes first ionizer 15A and second ionizer 15B. Specifically, as shown in FIG. 5, conveyance device 10 of the present exemplary embodiment includes first ionizer 15A (or an upper ionizer) corresponding to ionizer 15 of the first exemplary embodiment and second ionizer 15B (or a lower ionizer) disposed below first ionizer 15A. First ionizer 15A ejects neutralization air to substrate 30 in a first conveyance operation from above. On the other hand, second ionizer 15B ejects neutralization air to substrate 30 in a second conveyance operation from below. Second ionizer 15B of the present exemplary embodiment is a fixed ionizer.

### Modification of Second Exemplary Embodiment

A modification of the second exemplary embodiment of the present disclosure will be described. Conveyance device 10 of the present modification is different from that of the second exemplary embodiment in that second ionizer 15B is a movable ionizer.

Specifically, as illustrated in FIG. 6, second ionizer 15B of the present modification is attached to a lower surface of conveyance arm 13a of conveyor 13, and moves in housing 11 together with conveyor 13. Since conveyance arm 13a holds substrate 30 on an upper surface thereof, second ionizer 15B of the present modification also ejects neutralization air from below to substrate 30 in a second conveyance operation.

### Supplementary Note

Techniques below are disclosed by the description above of the exemplary embodiments.

### Technique 1

A conveyance device including:
a container that contains a processing target;
a conveyor that conveys the processing target along a predetermined conveyance path between the container and a processor that processes the processing target;
an ionizer that ejects neutralization air toward the processing target conveyed by the conveyor; and
a controller that controls the conveyor,
in which the processing target is held by a frame-attached holding sheet,
the controller causes the conveyor to execute
a first conveyance operation of delivering the processing target taken out from the container to the processor, and
a second conveyance operation of delivering the processing target received from the processor to the container, and
a neutralization condition of the ionizer in the first conveyance operation and a neutralization condition of the ionizer in the second conveyance operation are individually set.

### Technique 2

The conveyance device according to Technique 1, further including:
a first measurement unit that is disposed on a side of the container in the conveyance path and measures a charge amount of the processing target taken out from the container by the conveyor; and
a second measurement unit that is disposed on a side of the processor in the conveyance path and measures a charge amount of the processing target received by the conveyor from the processor,
in which the controller
determines the neutralization condition in the first conveyance operation based on the charge amount measured by the first measurement unit when the conveyor performs the first conveyance operation, and
determines the neutralization condition in the second conveyance operation based on the charge amount measured by the second measurement unit when the conveyor performs the second conveyance operation.

### Technique 3

The conveyance device according to Technique 1 or 2, in which the neutralization condition includes an air volume of the neutralization air ejected from the ionizer.

### Technique 4

The conveyance device according to any one of Techniques 1 to 3, in which the neutralization condition includes a stay time at a neutralization position set in a region where a distance from the ionizer is less than or equal to 250 mm, of the processing target conveyed by the conveyor.

### Technique 5

The conveyance device according to Technique 4, in which the controller adjusts the stay time by adjusting a stop time of the processing target at the neutralization position.

### Technique 6

The conveyance device according to Technique 4, in which the controller adjusts the stay time by adjusting a conveyance speed of the processing target at the neutralization position.

### Technique 7

The conveyance device according to any one of Techniques 1 to 6, in which the neutralization condition includes a distance between the processing target and the ionizer at a neutralization position set in a region where a distance from the ionizer is less than or equal to 250 mm.

### Technique 8

The conveyance device according to any one of Techniques 1 to 7, in which the ionizer includes
a first ionizer that ejects the neutralization air to the processing target in the first conveyance operation from above, and
a second ionizer that ejects the neutralization air to the processing target in the second conveyance operation from below.

### Technique 9

The conveyance device according to any one of Techniques 1 to 8, in which the processing target that the conveyor takes out from the container and delivers to the processor in the first conveyance operation is a wafer before singulation held on the frame-attached holding sheet,
the processor is a plasma processing chamber that singulates the wafer into a plurality of element chips, and
the processing target that the conveyor receives from the processor and delivers to the container in the second conveyance operation is the plurality of element chips held on the frame-attached holding sheet.

### technique 10

A conveyance method executed in a conveyance device including
a container that contains a processing target,
a conveyor that conveys the processing target along a predetermined conveyance path between the container and a processor that processes the processing target, and
an ionizer that ejects neutralization air toward the processing target conveyed by the conveyor,
the processing target being held by a frame-attached holding sheet,
the conveyance method including:
a first conveyance step of taking out the processing target from the container and then delivering the taken-out processing target to the processor by the conveyor; and
a second conveyance step of receiving the processing target from the processor and then delivering the received processing target to the container by the conveyor,
in which a neutralization condition of the ionizer in the first conveyance step and a neutralization condition of the ionizer in the second conveyance step are individually set.

### Technique 11

The conveyance method according to Technique 10, further including:
a first measurement step of measuring a charge amount of the processing target taken out from the container by the conveyor on a side of the container in the conveyance path;
a second measurement step of measuring a charge amount of the processing target received by the conveyor from the processor on a side of the processor in the conveyance path;
a first determination step of determining the neutralization condition in the first conveyance step based on the charge amount measured in the first measurement step; and
a second determination step of determining the neutralization condition in the second conveyance step based on the charge amount measured in the second measurement step.

### Technique 12

The conveyance method according to Technique 10 or 11, in which the neutralization condition includes an air volume of the neutralization air ejected from the ionizer.

### technique 13

The conveyance method according to any one of Techniques 10 to 12, in which the neutralization condition includes a stay time at a neutralization position set in a region where a distance from the ionizer is less than or equal to 250 mm, of the processing target conveyed by the conveyor.

### technique 14

The conveyance method according to Technique 13, further including a first adjustment step of adjusting the stay time by adjusting a stop time of the processing target at the neutralization position.

### Technique 15

The conveyance method according to Technique 13, further including a second adjustment step of adjusting the stay time by adjusting a conveyance speed of the processing target at the neutralization position.

### Technique 16

The conveyance method according to any one of Techniques 10 to 15, in which the neutralization condition includes a distance between the processing target and the ionizer at a neutralization position set in a region where a distance from the ionizer is less than or equal to 250 mm.

### Technique 17

The conveyance method according to any one of Techniques 10 to 16, in which the ionizer includes
a first ionizer that ejects the neutralization air to the processing target in the first conveyance step from above, and
a second ionizer that ejects the neutralization air to the processing target in the second conveyance step from below.

### Technique 18

The conveyance method according to any one of Techniques 10 to 17, in which the processing target that the conveyor takes out from the container and delivers to the processor in the first conveyance step is a wafer before singulation held on the frame-attached holding sheet,
the processor is a plasma processing chamber that singulates the wafer into a plurality of element chips, and
the processing target that the conveyor receives from the processor and delivers to the container in the second conveyance step is the plurality of element chips held on the frame-attached holding sheet.

The present disclosure is applicable to a conveyance device and a conveyance method.

What is claimed is:

1. A conveyance device comprising:
a container that contains a processing target;
a conveyor that conveys the processing target along a predetermined conveyance path between the container and a processor that processes the processing target;
an ionizer that ejects neutralization air toward the processing target conveyed by the conveyor; and
a controller that controls the conveyor,
wherein the processing target is held by a frame-attached holding sheet,
the controller causes the conveyor to execute
a first conveyance operation of delivering the processing target taken out from the container to the processor, and
a second conveyance operation of delivering the processing target received from the processor to the container, and
a neutralization condition of the ionizer in the first conveyance operation and a neutralization condition of the ionizer in the second conveyance operation are individually set.

2. The conveyance device according to claim 1, further comprising:
a first measurement unit that is disposed on a side of the container in the conveyance path and measures a charge amount of the processing target taken out from the container by the conveyor; and
a second measurement unit that is disposed on a side of the processor in the conveyance path and measures a charge amount of the processing target received by the conveyor from the processor,
wherein the controller
determines the neutralization condition in the first conveyance operation based on the charge amount measured by the first measurement unit when the conveyor performs the first conveyance operation, and
determines the neutralization condition in the second conveyance operation based on the charge amount measured by the second measurement unit when the conveyor performs the second conveyance operation.

3. The conveyance device according to claim 1, wherein the neutralization condition includes an air volume of the neutralization air ejected from the ionizer.

4. The conveyance device according to claim 1, wherein the neutralization condition includes a stay time at a neutralization position set in a region where a distance from the ionizer is less than or equal to 250 mm, of the processing target conveyed by the conveyor.

5. The conveyance device according to claim 4, wherein the controller adjusts the stay time by adjusting a stop time of the processing target at the neutralization position.

6. The conveyance device according to claim 4, wherein the controller adjusts the stay time by adjusting a conveyance speed of the processing target at the neutralization position.

7. The conveyance device according to claim 1, wherein the neutralization condition includes a distance between the processing target and the ionizer at a neutralization position set in a region where a distance from the ionizer is less than or equal to 250 mm.

8. The conveyance device according to claim 1, wherein the ionizer includes
a first ionizer that ejects the neutralization air to the processing target in the first conveyance operation from above, and
a second ionizer that ejects the neutralization air to the processing target in the second conveyance operation from below.

9. The conveyance device according to claim 1, wherein the processing target that the conveyor takes out from the container and delivers to the processor in the first conveyance operation is a wafer before singulation held on the frame-attached holding sheet,
the processor is a plasma processing chamber that singulates the wafer into a plurality of element chips, and
the processing target that the conveyor receives from the processor and delivers to the container in the second conveyance operation is the plurality of element chips held on the frame-attached holding sheet.

10. A conveyance method executed in a conveyance device including
a container that contains a processing target,
a conveyor that conveys the processing target along a predetermined conveyance path between the container and a processor that processes the processing target, and
an ionizer that ejects neutralization air toward the processing target conveyed by the conveyor,
the processing target being held by a frame-attached holding sheet,
the conveyance method comprising:
a first conveyance step of taking out the processing target from the container and then delivering the taken-out processing target to the processor by the conveyor; and
a second conveyance step of receiving the processing target from the processor and then delivering the received processing target to the container by the conveyor,
wherein a neutralization condition of the ionizer in the first conveyance step and a neutralization condition of the ionizer in the second conveyance step are individually set.

11. The conveyance method according to claim 10, further comprising:
a first measurement step of measuring a charge amount of the processing target taken out from the container by the conveyor on a side of the container in the conveyance path;
a second measurement step of measuring a charge amount of the processing target received by the conveyor from the processor on a side of the processor in the conveyance path;
a first determination step of determining the neutralization condition in the first conveyance step based on the charge amount measured in the first measurement step; and
a second determination step of determining the neutralization condition in the second conveyance step based on the charge amount measured in the second measurement step.

12. The conveyance method according to claim 10, wherein the neutralization condition includes an air volume of the neutralization air ejected from the ionizer.

13. The conveyance method according to claim 10, wherein the neutralization condition includes a stay time at a neutralization position set in a region where a distance from the ionizer is less than or equal to 250 mm, of the processing target conveyed by the conveyor.

14. The conveyance method according to claim 13, further comprising a first adjustment step of adjusting the stay time by adjusting a stop time of the processing target at the neutralization position.

15. The conveyance method according to claim 13, further comprising a second adjustment step of adjusting the stay time by adjusting a conveyance speed of the processing target at the neutralization position.

16. The conveyance method according to claim 10, wherein the neutralization condition includes a distance between the processing target and the ionizer at a neutralization position set in a region where a distance from the ionizer is less than or equal to 250 mm.

17. The conveyance method according to claim 10, wherein the ionizer includes
a first ionizer that ejects the neutralization air to the processing target in the first conveyance step from above, and
a second ionizer that ejects the neutralization air to the processing target in the second conveyance step from below.

18. The conveyance method according to claim 10, wherein the processing target that the conveyor takes out from the container and delivers to the processor in the first conveyance step is a wafer before singulation held on the frame-attached holding sheet,
the processor is a plasma processing chamber that singulates the wafer into a plurality of element chips, and
the processing target that the conveyor receives from the processor and delivers to the container in the second conveyance step is the plurality of element chips held on the frame-attached holding sheet.
